(19) United States
(12) Patent Application Publication
(10) Pub. No.: US 2022/0286114 A1
(43) Pub. Date: Sep. 8, 2022

(54) SIGNAL PROCESSING APPARATUS FOR GENERATING A PLURALITY OF OUTPUT SAMPLES

(71) Applicant: Advantest Corporation, Tokyo (JP)

(72) Inventor: Christian VOLMER, Stuttgart (DE)

(21) Appl. No.: 17/751,325

(22) Filed: May 23, 2022

Related U.S. Application Data
(63) Continuation of application No. PCT/EP2019/086996, filed on Dec. 23, 2019.

(51) Int. Cl. H03H 17/06; H03H 17/02

(52) U.S. Cl. CPC H03H 17/0657; H03H 17/0288; H03H 17/028

(57) ABSTRACT

Embodiments of the present invention provide a digital signal processing apparatus, including an interpolator, an interpolating convolver, or the like, for providing a plurality of output samples or output values in parallel, such as P output samples provided by P Farrow cores, based on a set of input samples or input values, such as 2P+M−2 samples. The digital signal processing apparatus includes a sample distribution logic or structure configured to provide a plurality of subsets of the set of input samples to a plurality of processing cores, such as interpolation cores (e.g., Farrow cores) that perform processing operations associated with different time shifts, for example with respect to a reference time (e.g., a time associated with the input samples). The sample distribution logic includes a hierarchical tree structure having a plurality of hierarchical levels of splitting nodes.

### CROSS-REFERENCE TO RELATED APPLICATIONS

This application claims the benefit of and priority to international patent application PCT/EP2019/086996, with filing date Dec. 23, 2019, which is hereby incorporated by reference in its entirety.

### FIELD

Embodiments of the present invention relate to digital signal processing. More specifically, embodiments relate to real-time waveform generation on digital signal processors.

### BACKGROUND

Interpolation typically involves upsampling and filtering data to produce an approximation of a sequence. In the case of an “interpolating” convolver, the output sampling is generally denser than the input sampling, which can present challenges.

An interpolator or an “interpolating convolver” convolves an input waveform with a continuous-time impulse response using equidistant sampling to produce a result with different sampling, which may or may not be equidistant. The interpolator can be based on an algorithmic architecture for use with an application specific integrated circuit (ASIC) or field-programmable gate array (FPGA). A Farrow interpolator is one example of a interpolator often used for these purposes. The impulse response of the Farrow interpolator is typically described in a piecewise polynomial fashion.

Interpolating digital convolution can be performed on a sequential digital signal processor (DSP). A time accumulator accumulates fractional samples in a half-open interval [0:1) with an increment of Δt. When the time accumulator overflows, it requests one input sample. The most recent input sample and a plurality of previous input samples are stored in an input register. The stored input samples are fed to finite impulse response (FIR) cores. The coefficients of the FIR cores determine the continuous time convolution kernel and the response of the interpolator in a piecewise polynomial fashion. The results of the FIR operations are used as the coefficients of a polynomial in a polynomial evaluator. The polynomial is evaluated with the fractional part of the accumulated time as an independent variable. The Farrow interpolator processes one sample at a time and produces one output sample per clock cycle (the standard Farrow implementation has a parallelism of one). Farrow interpolators typically support sequential digital processing only.

When the sample rate is higher than the clock rate of the digital signal processor, there is a recognized need for performing parallel processing operations (e.g., parallel processing on a common set of samples) while keeping sample distribution reasonably small.

### SUMMARY

Accordingly, embodiments of the present invention provide a digital signal processing apparatus that includes an interpolator, an interpolating convolver, or the like, for providing a plurality of output samples or output values in parallel (e.g., P output samples provided by P Farrow cores) based on a set of input samples or input values (e.g., 2P+M −2 samples). The digital signal processing apparatus includes a sample distribution logic or structure configured to provide a plurality of subsets of the set of input samples to a plurality of processing cores, such as interpolation cores (e.g., Farrow cores) that perform processing operations associated with different time shifts, for example with respect to a reference time (e.g., a time associated with the input samples). The sample distribution logic includes a hierarchical tree structure having a plurality of hierarchical levels of splitting nodes.

According to one embodiment, a signal processing apparatus for providing a plurality of output samples based on a plurality of input samples is disclosed. The signal processing apparatus includes a sample distribution logic unit operable to provide input samples of the plurality of input samples to a plurality of processing cores, where the plurality of processing cores are operable to perform processing operations on the input samples associated with different time shifts, and the apparatus further includes a hierarchical tree structure including a plurality of hierarchical levels. The plurality of hierarchical levels include input samples of the plurality of input samples. The apparatus further includes a first splitting node associated with a lowest hierarchical level of the hierarchical tree structure operable to provide two or more subsets to a plurality of processing cores coupled to the first splitting node, and a second splitting node associated with a hierarchical level that is higher than the lowest hierarchical level, where the second splitting node is operable to provide two or more subsets of input samples of the plurality of input samples associated with the second splitting node to a plurality of subtrees coupled to the second splitting node. The first and second splitting nodes are operable to select a subset of input of the plurality of input samples in accordance with a range of time shifts associated with the processing cores to generate the plurality of output samples.

According to some embodiments, the plurality of processing cores are further operable to perform processing operations associated with the range of time shifts in parallel to generate the plurality of output samples.

According to some embodiments, an input sample rate of the input samples is no greater than a target output sample rate of the output samples.

According to some embodiments, the signal processing apparatus includes an input register coupled to the sample distribution logic, and a time accumulator operable to track the time shift and to cause new input samples to be obtained by the input register when the time shift overflows a predetermined multiple of a sampling period of the input samples.

According to some embodiments, a number of input samples of a plurality of splitting nodes associated with a same hierarchical level are identical.

According to some embodiments, a number of input samples of a given splitting node is larger than a number of input samples provided to splitting nodes of a next lower hierarchical level and larger than a number of input samples provided to the plurality of processing cores as input samples.

According to some embodiments, the sample distribution logic unit is operable to provide input samples to the first and second splitting nodes according to the hierarchical tree in a step-wise manner that decreases with each hierarchical level of the hierarchical tree.

According to some embodiments, a number of input samples provided to the first and second splitting nodes is based on at least one of a number of input samples or subset of input samples provided to a single processing core of the plurality of processing cores, a hierarchical level of the first or second splitting node, and a factorization of a number of processing cores as integer factors.

According to some embodiments, a number of input samples provided by the first or second splitting node is based on a factorization of a number of processing cores as integer factors.

According to some embodiments, the first splitting node is associated with a first hierarchical level of the hierarchical tree structure, and a number of subsets of input samples provided by the first splitting node is based on a number of processing cores, a total number of factors of a selected integer factorization, and the first hierarchical level.

According to some embodiments, the number of subsets of input samples provided by the first splitting node is further based on a number of samples of a subset of samples provided to a single processing core.

According to some embodiments, the first and second splitting nodes are configured to assign input samples to a plurality of subtrees or processing cores, and provide assigned input samples to the respective subtrees of the hierarchical tree structure or to respective processing cores. A starting index of the assigned input samples is based on at least one of a hierarchy level associated with a splitting node, an integer factor for factorization of the number of processing cores, and a time shift and time information assigned to the assigned input samples.

According to some embodiments, the signal processing apparatus further includes an input register configured to store input samples.

According to some embodiments, the input register includes a shift register.

According to some embodiments, the signal processing apparatus includes a selector configured to select the subset of input samples from the plurality of input samples to provide to the sample distribution logic unit.

According to some embodiments, a length of the time shifts is equidistant.

According to some embodiments, the signal processing arrangement performs an interpolation between the plurality of input samples.

According to some embodiments, the sample distribution logic unit is operable to perform a convolution on the input samples.

According to some embodiments, the plurality of processing cores are operable to process the input samples using a Farrow structure.

According to a different embodiment, a method for generating a plurality of output samples based on a set of input samples is disclosed. The method includes accessing a plurality of subsets of input samples for processing using a hierarchical tree structure including a plurality of hierarchical levels, providing two or more input samples of a first subset of input samples associated with a lowest hierarchical level of the hierarchical tree structure to a splitting operation associated with the lowest hierarchical level. The splitting operation is operable to provide the two or more subsets to a plurality of processing cores coupled to the respective splitting operation of the lowest hierarchical level. The method further includes selecting two or more second subsets of input samples based on a plurality of time shifts associated with processing operations of a subtree of the hierarchical tree structure, providing two or more subsets of input samples to a plurality of subtrees coupled to the splitting operations of a higher hierarchical level of the plurality of hierarchical levels, and performing processing operations associated with first time shifts of the plurality of time shifts in parallel to generate output samples.

According to a different embodiment, a non-transitory computer-readable storage medium having embedded therein program instructions, which when executed by one or more processors of a device, causes the device to execute a method for generating a plurality of output samples based on a set of input samples is disclosed. The method includes accessing a plurality of subsets of input samples for processing using a hierarchical tree structure including a plurality of hierarchical levels, providing two or more input samples of a first subset of input samples associated with a lowest hierarchical level of the hierarchical tree structure to a splitting operation associated with the lowest hierarchical level, where the splitting operation is operable to provide the two or more subsets to a plurality of processing cores coupled to the respective splitting operation of the lowest hierarchical level. The method further includes selecting two or more second subsets of input samples based on a plurality of time shifts associated with processing operations of a subtree of the hierarchical tree structure, providing two or more subsets of input samples to a plurality of subtrees coupled to the splitting operations of a higher hierarchical level of the plurality of hierarchical levels, and performing processing operations associated with first time shifts of the plurality of time shifts in parallel to generate output samples.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 is a block diagram of an exemplary signal processing apparatus including a sample distribution logic and a plurality of processing cores according to embodiments of the present invention.

FIG. 2 is a block diagram of an exemplary signal processing apparatus including a time accumulator, an input register and a selector according to embodiments of the present invention.

FIG. 3 is a block diagram of an exemplary sample distribution logic splitting node according to embodiments of the present invention.

FIG. 4 is a block diagram of an exemplary splitting node that provides two output subsets based on input samples with time information according to embodiments of the present invention.

FIG. 5 is a block diagram of an exemplary Farrow interpolator according to embodiments of the present invention.

FIG. 6 is a block diagram of an exemplary extended signal processing apparatus using a binary tree according to embodiments of the present invention.

FIG. 7 is a block diagram of an exemplary extended signal processing apparatus using hierarchical levels of splitting nodes according to embodiments of the present invention.

FIG. 8 is a block diagram of an exemplary extended signal processing apparatus processed using Farrow cores according to embodiments of the present invention.

FIG. 9 is a flowchart depicting an exemplary sequence of computer implemented steps for generating a plurality of output samples based on a set of input samples according to embodiments of the present invention.

### DETAILED DESCRIPTION

In the following, different inventive embodiments and aspects will be described. Also, further embodiments will be defined by the enclosed claims.

It should be noted that any embodiments as defined by the claims may be supplemented by any of the details, features and functionalities described herein. Also, the embodiments described herein may be used individually, and may also optionally be supplemented by any of the details, features and functionalities included in the claims.

Also, it should be noted that individual aspects described herein may be used individually or in combination. Thus, details may be added to each of said individual aspects without adding details to another one of said aspects. It should also be noted that the present disclosure describes, explicitly or implicitly, features usable in a test arrangement or in an automatic test equipment (ATE). Thus, any of the features described herein may be used in the context of a test arrangement or in the context of an automatic test equipment.

Moreover, features and functionalities disclosed herein, relating to a method, may also be used in an apparatus configured to perform such functionality. Furthermore, any features and functionalities disclosed herein with respect to an apparatus may also be used in a corresponding method. In other words, the methods disclosed herein may be supplemented by any of the features and functionalities described with respect to the apparatuses.

The present invention will be understood more fully from the detailed description given below, and from the accompanying drawings of embodiments of the present invention, which, however, should not be taken to limit the present invention to the specific embodiments described, but are for explanation and understanding only.

### Signal Processing Arrangement for Generating a Plurality of Output Samples

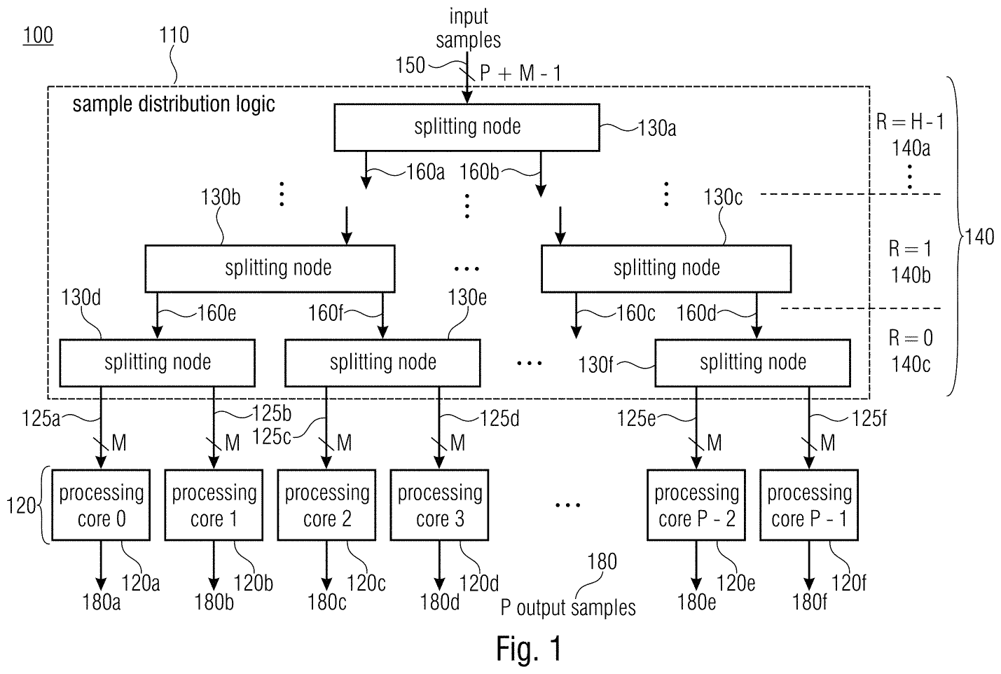

FIG. 1 is a block diagram depicting an exemplary digital signal processing apparatus 100 including a sample distribution logic (e.g., a logic module or unit) 110 and a plurality of processing cores 120. The sample distribution logic 110 includes a plurality of splitting nodes 130a-f organized in a hierarchical tree structure 140 having a plurality of hierarchical levels 140a-c. The input samples 150 of the digital signal processing apparatus 100 are provided to the sample distribution logic 110 as input samples, and the input samples 150 are provided to the splitting node 130a of the highest hierarchical level 140a. The splitting node 130a takes the input samples 150 as input and provides two or more subsets 160a, 160b from the input samples 150. Subsets on the same hierarchical level (e.g., subsets 160a-b on the level 140a or subsets 160c-f on the level 140b) have the same number of samples. For example, subsets 160a and 160b are accessed by splitting nodes 130b and 130c of the next lower hierarchical level 140b.

Splitting nodes 130a-f receive one set of input samples from the next higher hierarchical level. For example, splitting node 130c accesses or receives input samples 160b from a splitting node 130a on hierarchical level 140a, and provides two or more subsets (e.g., input samples 160c, 160d) to two or more splitting nodes (e.g., splitting node 130f) on the next lower hierarchical level (e.g., hierarchical level 140c).

The sample distribution logic uses a hierarchical tree structure 140 of splitting nodes 130a-f. Splitting node 130a of the highest hierarchical level receives input samples 150, and every other splitting node 130b-f receives a set of input samples from the next higher hierarchical level. The splitting nodes 130d-f on the lowest hierarchical level 140c are coupled with two or more processing cores, and the other splitting node 130a-c of the sample distribution logic 110 are coupled with two or more splitting nodes 130b-f of the next lower hierarchical level.

The processing cores 120 include processing cores 120a-f with inputs coupled to a splitting node 130d-f of the lowest hierarchical level 140c of the distribution logic 110. Processing core 120b is coupled to a single splitting node 130d of the lowest hierarchical level 140c of the sample distribution logic 110, and the splitting node 130d of the lowest hierarchical level 140c of the sample distribution logic 110 is coupled to two or more processing cores 120a, 120b of the digital signal processing apparatus 100. The set of input samples 125b of a given processing core 120b is provided by a splitting node 130d of the lowest hierarchical level 140c of the sample distribution logic 110 coupled to the given processing core 120b. Processing cores 120a-f can be configured to provide a single output sample 180a-f from a respective set of input samples 125a-f The plurality of processing cores 120 perform processing operations in parallel to provide a plurality of output samples 180 with the processing operations being associated with different time shifts.

As mentioned above, digital signal processing apparatus 100 can be configured to provide a plurality of output samples 180 from a set of input samples 150. The plurality of processing cores 120 perform processing operations in parallel with processing cores 120a-f associated with different time shifts. The set of input samples 125a-f of the processing cores 120a-f are provided by the sample distribution logic 110. The sample distribution logic 110 provides subsets 125a-f of the set of input samples 150 using a hierarchal tree structure 140 including splitting nodes 130a-f organized in hierarchical levels 140a-c.

The input samples 150 are distributed into subsets 125a-f, which are fed into the processing cores 120a-f as input. The number of samples in the subsets 125a-f is equal for all of the subsets 125a-f according to embodiments. Each level 140a-c of the sample distribution logic 110 includes splitting nodes 130a-f. Splitting node 130a-f of a given hierarchical level 140a-c receive one set of input samples from the next higher hierarchical level and provide two or more subsets 160a-d, 125a-f for the next lower hierarchical level 140a-c.

The digital signal processing apparatus 100 or a parallel interpolating digital convolver 100 described herein according to embodiments of the present invention may be used as a building block of a signal processor application-specific integrated circuit (ASIC) and/or as part of other instruments. Applications of the digital signal processing apparatus 100 can be addressed on a parallel DSP (real-time or near to real-time) for flexible or very high sample rates to implement a parallel area-efficient architecture. For example, the digital signal processing apparatus can be addressed using a sample rate of 100 GSa/s in real-time.

Further, the signal processing apparatus can be used to provide a high quality and flexible sample rate conversion for radio frequency (RF) and analogue baseband applications in real-time. The usable bandwidth can be 75% of the Nyquist rate and can achieve 60 dB image suppression, for example. Very high sample rates far beyond the clock rate of the DSP can be addressed. The conversion ratio is not significantly limited and is flexible in that it can be configured as a number between 0 and 1 with 64 bits of resolution, for example.

Moreover, the signal processing apparatus can be used to provide pulse-shaping for the generation of non-return-to-zero (NRZ) digital waveforms and/or pulse-amplitude modulation (PAM) digital waveforms for flexible (or almost arbitrary) user bit rates. In a non-equidistant sampling case the signal processing apparatus can also be used to provide an injection of memory-based timing jitter. In one example, a fractional sub-sample delay for a time-to-digital (TDC) based synchronization mechanism is provided.

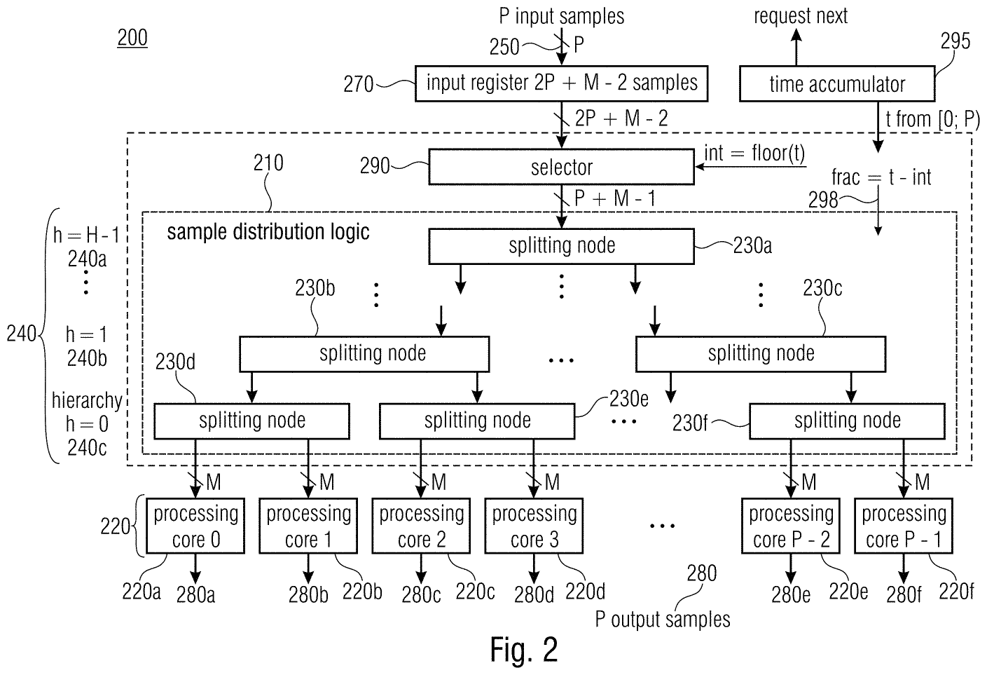

FIG. 2 is block diagram depicting an exemplary signal processing apparatus 200, which can be a version of the digital signal processing apparatus 100 depicted in FIG. 1, according to embodiments of the present invention. The input of the digital signal processing apparatus 200 is coupled to an input register 270 (e.g., a shift register). The input register 270 has one input and one output. The input of input register 270 is provided by digital signal processing apparatus 200, and the output is coupled to a selector 290.

Selector 290 has two inputs and one output. A first input of the selector is coupled to the input register 270 and a second input of the selector 290 is coupled to a time accumulator 295. The output of the selector 290 is coupled to a sample distribution logic 210, which may be similar to the sample distribution logic 110 of FIG. 1. The time accumulator 295 is configured to trigger new samples for the digital signal processing apparatus 200 and is coupled with the selector 290 and the sample distribution logic 210. The sample distribution logic 210 includes a hierarchical tree structure of splitting nodes 230a-f organized as different hierarchical levels 240.

The input of the splitting node 230a on the highest hierarchical level 240a of the sample distribution logic 210 is the input of the sample distribution logic 210 and is coupled to the selector 290. Splitting node 230a has two or more outputs coupled to different splitting nodes 230b-c on the next lower hierarchical level, for example level 240b.

Splitting node 230a-f of the sample distribution logic 210 can have one input and two or more outputs. The input of the given splitting node 230a-f is coupled to another splitting node 230a-f on a next higher hierarchical level 240a-c, and the outputs of the splitting nodes 230a-f is coupled to different splitting nodes 230a-f on a next lower hierarchical level 240a-c.

The sets of output samples of the splitting nodes 230d-f of the lowest hierarchical level 240c are the sets of output samples of the sample distribution logic 210. Splitting nodes 230d-f of the lowest hierarchical level 240c of the sample distribution logic 210 are coupled to two or more processing cores 220a-f of processing cores 220, which may be similar to processing cores 120 of FIG. 1.

Any of the processing cores 220a-f (e.g., processing core 220b) has one input and one output. The processing cores 220a-f expect a set of input samples from a coupled splitting node 230a-f as input, and provide a single output sample 280a-f The single output samples 280a-f are output samples 280 of the signal processing apparatus 200. In other words, digital signal processing apparatus 200 includes digital signal processing apparatus 100, which is extended to include an input register 270, a selector 290 and a time accumulator 295.

The time accumulator 295 is configured to track the time shift and to trigger acquisition of new input samples 250 in the input register 270, whenever the time shift overflows the predetermined multiple, for example P, of a sampling period. The input register 270 is a shift register configured to store a plurality of input samples 250 (e.g., 2P+M−2 samples) and is coupled to the sample distribution logic 210 via a selector block 290. Selector block 290 is coupled to both the input register 270 and the sample distributing logic 210 and is configured to select a set of input samples from the input samples stored in the input register 270 for the sample distribution logic 210.

The input samples of the sample distribution logic 210, selected by the selector 290, can be input samples of the first splitting node 230a in the first hierarchical layer 240a along with time information 298. A splitting node 230a-f of hierarchical levels 240a-c is configured to assign time information to each subtree or subsets of the input samples, where the time information is based on a time shift tracked by the time accumulator 295. Each splitting node 230a-f of a sample distribution logic 210 can be configured to divide the set of input samples into subsets and provide the subsets as output to a splitting node 230a-f on a next lower hierarchical level.

According to some embodiments, splitting nodes 230a-f of respective hierarchical levels 240a-c are configured to assign a time information 298 to each subtree based on:
1. the time information assigned to the input samples of the respective splitting node 230a-f;
2. the hierarchical level 240a-c of the respective splitting node 230a-f;
3. an integer factor of the number of processing cores 220a-f; and/or
4. the time shift 298.

The length of time shift 298 tracked by the time accumulator 295 may be equidistant or non-equidistant if timing jitter is applied. A splitting node 230d-f of the lowest hierarchical level 240c supplies a processing core 220a-f coupled to the given splitting node 230d-f so that the processing cores 220a-f provide a respective output sample 280a-f. The processing cores 220a-f can include a Farrow core and can receive a subset of M samples of the input samples stored in an input register 270, preselected by a selector 290 and distributed by an area efficient implementation of the distribution logic 210, for example.

The digital signal processing apparatus 200 can perform the same and/or similar mathematical operations as a Farrow interpolator, and can process P samples at once per clock cycle. It produces P time-consecutive output samples per clock with a parallelism greater than 1. In the example of FIG. 2, every splitting node has two outputs, and the number P is a power of two. The plurality of processing cores includes P identical processing cores, or Farrow cores. Each core can include FIR filter cores and a polynomial evaluator used in a Farrow core or a particular Farrow implementation.

The time accumulator 295 accumulates fractional samples in the half-open interval [0; P) in increment of P×Δt. Whenever the time shift overflows a predetermined multiple, such as P, the time accumulator requests or accesses P input samples 250. The input samples are stored in an input register 270, which is capable of storing 2P+M−2 samples, and contains P current samples and P+M−2 past samples. From this 2P+M−2 samples the selector 290 selects P+M−1 samples as a set of input samples of the sample distribution logic 210. The P+M−1 input samples of the sample distribution logic 210 are distributed between P processing cores 220a-f, where each processing core 220a-f is fed by M samples. The plurality of processing cores 220a-f includes P identical processing cores or Farrow cores. Each processing core (or Farrow core) includes an FIR filter core and a polynomial evaluator used in a Farrow implementation. Every such core takes M input samples and computes one of the P output samples 280a-f.

The distribution of samples proceeds in two stages: a selection or pre-selection and splitting. The selection process performed by a selector 290 includes picking a continuous sub-range of P+M−1 samples eligible for further processing from the input register 270. The selection is based on the integer part of the time shifts accumulated by the time accumulator in the closed interval [0; P−1].

The splitting stage splits the selected sub-range such that every processing core (e.g., Farrow core) 220a-f the correct series of M input samples. When P=2^{H}, the splitting process involves a hierarchical structure 240, which is a perfect binary tree with a height of H−1. H hierarchical levels are used with P/2^{h+1} splitting nodes at hierarchy level h, where h=0 . . . H−1. The 2^{H-1} splitting nodes at the lowest hierarchical level h=0 produce P sets of M samples each, which is suitable for P processing cores.

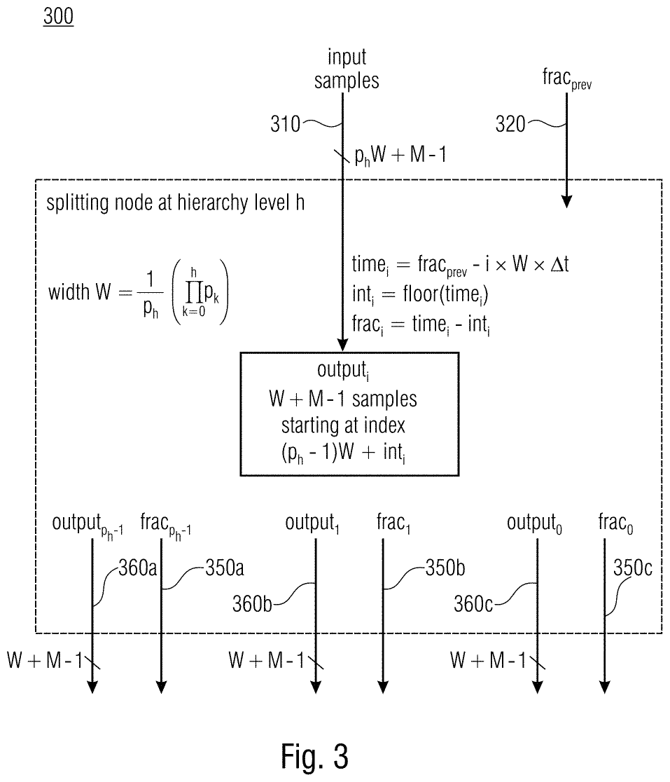

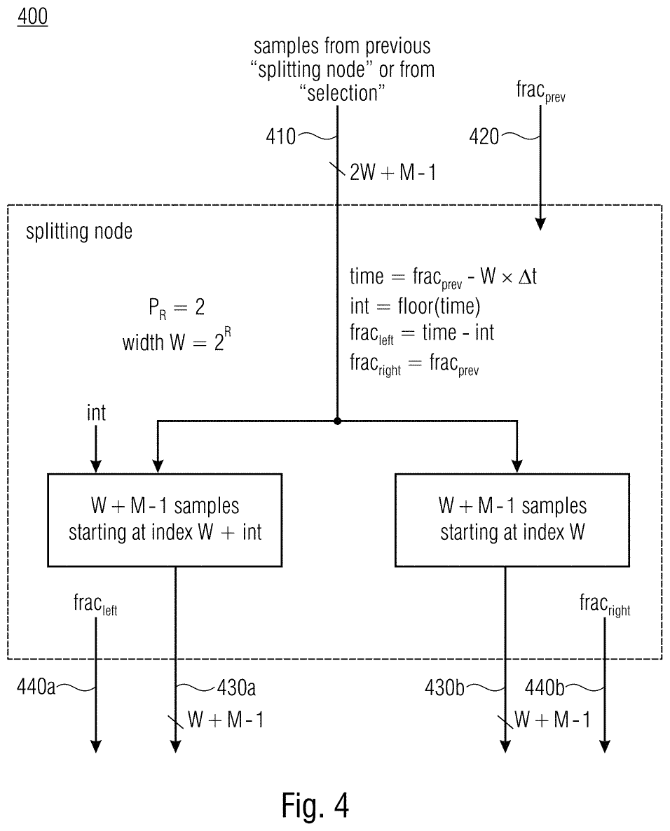

An exemplary operation of a splitting node at a hierarchy level h is depicted in FIG. 3. An exemplary splitting node for the perfect binary tree (e.g., where P=2^{H} and pₖ=2 for all k=0 . . . H−1) is described herein with regard to the example of FIG. 4 below.

FIG. 3 is a block diagram depicting an exemplary splitting node 300 which may be similar to splitting node 130 depicted FIG. 1 according to embodiments of the present invention. Inputs of the splitting node 300 include input samples 310 and time information 320. The splitting node 300 provides two or more subsets 360a-c of the input samples 310 with respective associated time information 350a-c. When splitting node 300 is used at a given hierarchical level, h, it is configured to divide the set of input samples 310 into a plurality of subsets 360a-c of the input samples 310. The subsets 360a-c have the same number of samples, for example W+M−1 samples, wherein W is defined as

$$W = \frac{1}{{p}_{h}} ( {\prod }_{k = 0}^{h} {p}_{k} ) ,$$

wherein pₖ represent integer factors of the number of processing cores.

The W+M−1 samples of a subset are selected from the pₕW+M−1 input samples 310 by selecting subsets of the input samples 310 containing W+M−1 samples beginning at a starting index based on time information 320 provided to the splitting node 300. The starting index of the subset of input samples provided to the subtree with index i of a respective splitting node can be determined using the following the equation, where fracₚᵣₑᵥ 320 represents the time information associated with the input samples:

indexᵢ=(pₕ−1)W+└fracₚᵣₑᵥ−i×W×Δt┘.

According to embodiments, splitting node 300 can be configured to associate time information 350a-c with the respective subset 360a-c provided by a splitting node 300. The time information 350a-c associated with the subsets 360a-c are based on the time information 320 provided to the splitting node 300, the respective hierarchical level of the splitting node 300, and/r an integer factor of the number of processing cores 120 of FIG. 1.

The time information 350a-c can be based on the following equation:

fracᵢ=(fracₚᵣₑᵥ−i×W×Δt)−└fracₚᵣₑᵥ−i×W×Δt┘.

Splitting node 300 depicted in FIG. 3 can be used in digital signal processing apparatus 100 of FIG. 1 according to embodiments of the present invention. Splitting nodes 300 are organized in a hierarchical tree structure in a sample distribution logic 110 as depicted in FIG. 1 to divide the input samples 150 of FIG. 1 into subsets of input samples with equal sample sizes to serve as input samples or a sets of input samples for the plurality of processing cores 120 on FIG. 1.

FIG. 4 is a diagram of an exemplary splitting node 400 that receives a set of input samples 410 and time information 420 as input, and provides two sets of output samples 430a, 430b with respective time information 440a, 440b, according to embodiments of the present invention. FIG. 4 depicts the binary tree structure that results when the number of processing cores is a power of two (e.g., P=2^{H}), and this number is factored according to P=Πₖ₌₀^{H-1}pₖ with all pₖ=2.

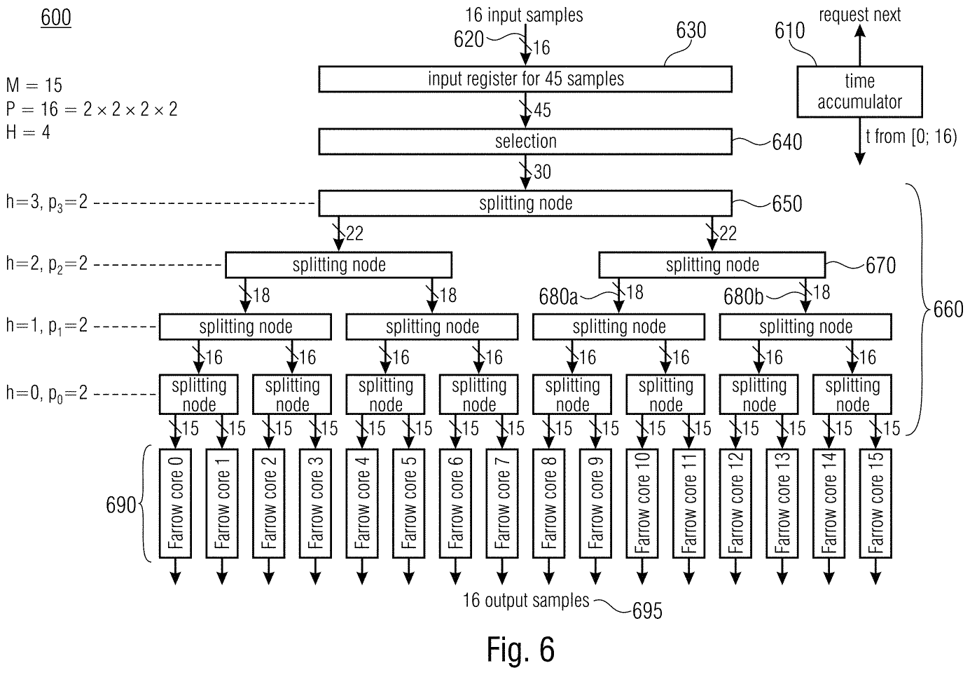

Each subset 430a, 430b is configured to contain W+M−1 samples, selected from the input samples 410 starting at different indices, and the starting index is based on the time information 420. Splitting node 400 can be used in a sample distribution logic (e.g., sample distribution logic 110 of FIG. 1 or sample distribution logic 660 of FIG. 6) to divide the input samples 410 into two output subsets 430a, 430b with equal number of samples, and with associated time information 440a, 440b, respectively. The time information 440a, 440b are based on the input timing information 420. The output subsets 430a, 430b can be output subsets of a next higher hierarchical level of splitting node 130 depicted in FIG. 1, for example.

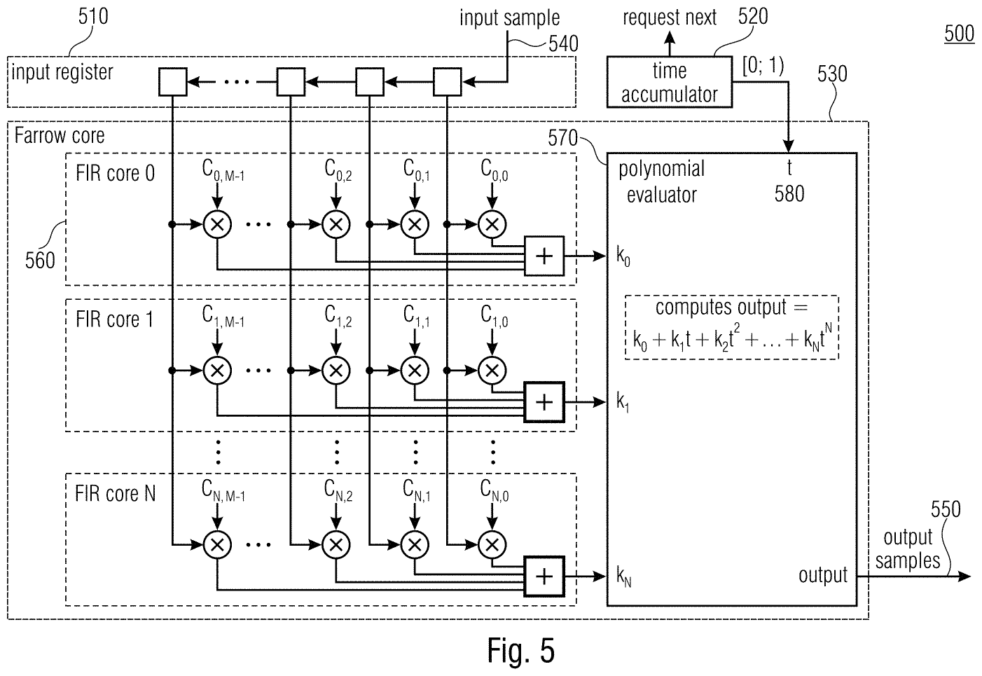

FIG. 5 is a block diagram depicting a conventional Farrow interpolator 500 according to embodiments of the present invention. The Farrow interpolator 500 includes an input register 510, a time accumulator 520 and a Farrow core 530. The time accumulator 520 accumulates fractional samples in the half-open interval [0; 1) with an increment of Δt. When the accumulator overflows, it requests one input sample 540. The most recent input sample 540 and previous input samples (e.g., M−1 samples) are stored in the input register 510. The total number of the input samples stored in the input register 510 for the computations of the interpolation may be called the support M of the Farrow interpolator 500.

The input register 510 and the time accumulator 520 are coupled to the Farrow core 530. The Farrow core 530 of the Farrow interpolator 500 produces one output sample 550 per clock cycle, and an input sample 540 is provided and/or requested when the time accumulator 520 overflows.

The Farrow core 530 includes a plurality of finite impulse response (FIR) cores 560 and a polynomial evaluator unit 570. The input register 510 is coupled to each FIR cores 560 of the Farrow core 530. Each FIR core 560 is coupled to the polynomial evaluator 570. The polynomial evaluator 570 takes input from the FIR cores 560, and fractional time input 580 from the time accumulator 520, and provides one output sample 550 per clock cycle, which is the output of the Farrow interpolator 500.

The time accumulator accumulates fractional time 580 and provides it to the polynomial evaluator 570 of the Farrow core 530. When the time accumulator 520 overflows, it requests a new input sample 540. The new input sample 540 is stored in the input register 510, which is configured as a shift register. The input register 510 stores the new input sample 540 and the previous input samples (e.g., M−1 input samples). The set of input samples (e.g., M input samples stored in the input register 510) are provided to the Farrow core 530, specifically to the FIR cores 560 of the Farrow core 530.

Each FIR core 560 calculates a weighted average value of the input samples stored in the input register 510, and the FIR cores may have different weights and/or different coefficients for the weighted average calculation. The weighted average values provided by the FIR cores 560 are provided to the polynomial evaluator 570. Using the calculated weighted averages (calculated by the FIR cores 560 as the coefficient values of a polynomial) and the fractional time value 580 (provided by the time accumulator 520 as an independent variable of the polynomial), the polynomial evaluator 570 computes the value of the polynomial and outputs this value as an output sample 550. Output sample 550 is the output of the Farrow core 530 and/or the output of the Farrow interpolator 500.

The Farrow interpolator 500 can be a conventional interpolator which processes one sample at a time (parallelism equal to 1). In contrast, the digital signal processing apparatus 100 depicted in FIG. 1 can be addressed on a parallel DSP, in real time or substantially real time for high sample rates. For example the digital signal processing apparatus 100 of FIG. 1 may address sample rates of 100 Gigasamples per second in real-time on a DSP having a clock speed less than 1 Gigahertz.

The digital signal processing apparatus 100 on FIG. 1 includes a plurality of processing cores 120 for parallel processing, and the processing cores 120 of FIG. 1 may include the Farrow cores 530 depicted in FIG. 5. According to some embodiments, sample distribution logic 110 FIG. 1 distributes the input values 150 on FIG. 1 to the multiple Farrow cores 530 used as a plurality of processing cores 120 on FIG. 1.

The signal processing apparatus uses a single time accumulator, for example time accumulator 295 of FIG. 2, instead of multiple time accumulators 520 per each processing cores (or Farrow cores 530) in the example of FIG. 5, thereby allowing the Farrow cores 530 to perform processing operations in parallel. The digital signal processing apparatus 100 of FIG. 1 can include processing cores 120 depicted in FIG. 1, and the processing cores 120 can include Farrow cores 530.

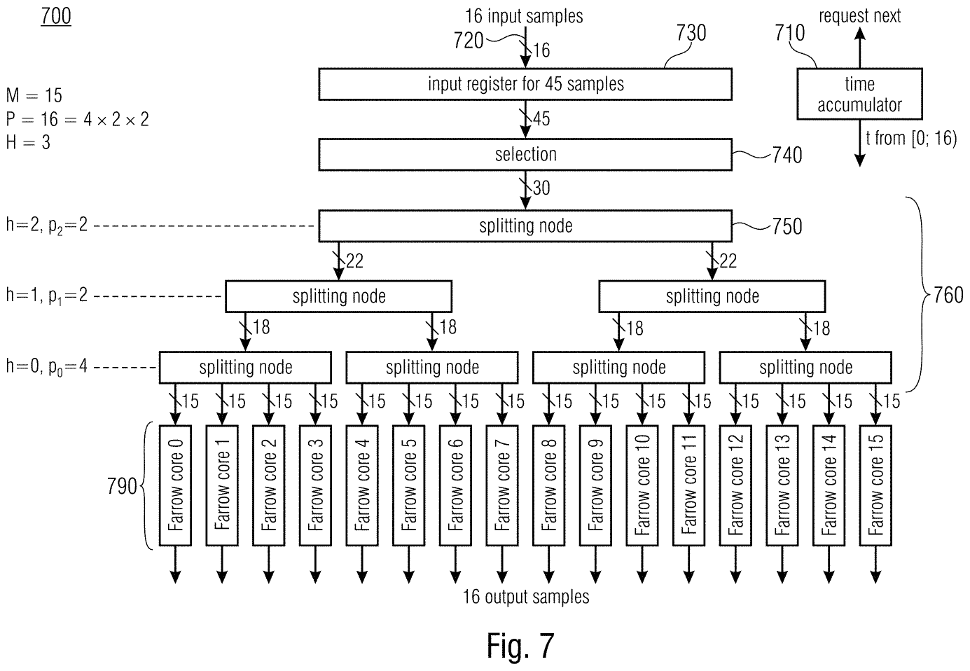

According to some embodiments, the processing cores or Farrow cores do not have to follow the original Farrow implementation. An output sample can be computed from zero or more input samples and fractional timing information qualifies and can be used in a signal processing apparatus. Embodiments can include a polyphase FIR filter, and the coefficients can be determined from the fractional timing information 580 using a mathematical relationship and/or a look-up table. The interpolation ratio can be 1 or more and the value can be variable. Moreover, the output sampling does not have to be equidistant. For example, the time/timing accumulator and the splitting logic or sample distribution logic can generate non-equidistant time points. The parallelism or number of processing cores P is not restricted to integer powers of two, although using integer powers of two can yield the most efficient implementation. Individual switches in the “splitting” or sample distribution stage can be combined (see, FIG. 7). According to some embodiments, intervals for representing time accumulation or fractional timing information can include [−0.5; P−0.5), [−0.5; 0.5) or [−1; 1).

FIG. 6 depicts an exemplary digital signal processing apparatus 600 including a time accumulator 610 configured to trigger new input samples 620, which are stored in the input register 630. The input register 630 is coupled to a selector unit 640, which provides input samples to a first splitting node 650. The splitting node 650 is a splitting node of a hierarchical tree structure 660. In the example of FIG. 6, hierarchical tree structure 660 is a binary tree. The splitting nodes in the binary tree structure 660 have one input and two outputs. The input samples 670 of a given splitting node are divided into subsets 680a, 680b of the inputs samples 670. The hierarchical tree structure provides an equal amount of input samples to the processing cores 690 or Farrow cores 690. Each of the Farrow cores 690 provide single output samples from the given sets of input samples provided by the splitting nodes on the lowest hierarchical level of the binary tree structure 660.

When the incremental accumulated time fractions Δt or a multiple time fractions (e.g., 16×Δt) overflows in the time accumulator 610, 16 new input samples are requested. The 16 new input samples are stored along with previous input samples in the input register 630. In the example of FIG. 6, 45 samples are stored in total. The selector unit 640 selects 30 samples of the 45 samples stored in the input register, and provides them as an input set of samples to the first splitting node 650. The first splitting node 650 provides two subsets with 22 samples each from the 30 samples of the set of input samples. The splitting nodes in the next lower hierarchical level receive 22 input samples, and receive output samples as two subsets with 18 samples. Splitting nodes in lower hierarchical levels receive progressively fewer samples as input samples, and the highest hierarchical level receives 30 samples as input samples. The next splitting nodes receive 22, 18, and 16 samples, respectively, as input samples in the lower hierarchical levels.

The samples in a subset provided by a splitting node are provided as input samples of a splitting node at the next hierarchical level. The first splitting node 650 provides two subsets of 22 samples from the 30 samples of the set of input samples. Splitting nodes in lower hierarchical levels provide 22, 18, 16, and 15 samples per subset from their set of input samples. The splitting nodes in the lowest hierarchical level of the sample distribution logic, or the hierarchical tree structure 660, provide two subsets with 15 samples each as input samples to a processor core or a Farrow core 690. The Farrow core 690 can be similar to the Farrow core 530 of FIG. 5, which produces one output sample from a set of input samples (e.g., 15 input samples in this example).

FIG. 7 is a block diagram of an exemplary digital signal processing apparatus 700 according to embodiments of the present invention. The signal processing apparatus 700 includes a time accumulator 710 that triggers a set of input samples 720 (16 input samples in the example of FIG. 7). The new input samples and the previous input samples are stored in the input register 730 (45 input samples in total). A selector unit 740 selects 30 input samples from the 45 total input samples and provides them as input sample to the splitting nodes 750 (e.g., to the first splitting node on the highest hierarchical level of a hierarchical tree structure 760 of splitting nodes 750).

The digital signal processing apparatus 600 in FIG. 6 and the digital signal processing apparatus 700 in FIG. 7 are capable of performing the similar computations. However, the factorization (e.g., 2×2×2×2 or 4×2×2) of the number of processing cores may be different. Moreover, while the hierarchical tree structure 660 of FIG. 6 is a binary tree, the hierarchical tree structure 760 has only three hierarchical levels. The splitting node of the lowest hierarchical level provides four subsets of the set of input samples.

In the example of FIG. 7, the splitting nodes on the lowest hierarchical level receive a set of input samples having 18 input samples each, and provide four subsets of the input samples with 15 samples in each subset to four processing cores. The processing cores 790 are Farrow cores, which may be similar or identical to the Farrow cores 530 depicted in FIG. 5, providing one output sample each from a set of input samples (e.g., from 15 input samples).

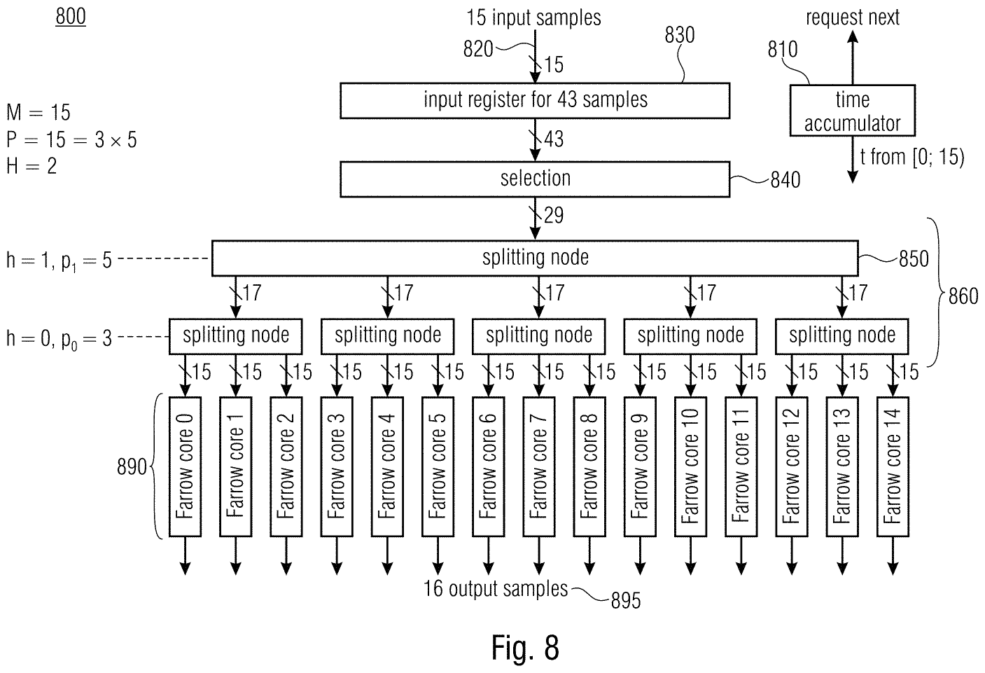

FIG. 8 depicts an exemplary digital signal processing apparatus 800 in a hierarchical tree structure 860 according to embodiments of the present invention. When the time accumulator 810 overflows, 15 input samples are obtained. The 15 input samples 820 are stored along with the previous input samples (43 samples in total) in the input registers 830.

Selector unit 840 selects 29 input samples from the 43 input samples to provide as input to the first splitting node. The splitting nodes 850 of the digital signal processing apparatus 800 are organized in a hierarchical tree structure 860. In the example of FIG. 8, the number of processing cores P is not a power and two and the hierarchical tree structure of the splitting nodes includes two hierarchical levels. The splitting node 850 on the highest hierarchical level provides five subsets of the input samples with 17 samples each, and the splitting nodes 850 on the second highest hierarchical level, which is the lowest hierarchical level, provide three subsets of the input samples with 15 samples each.

The 15 samples are provided to a plurality of processing cores 890, or Farrow cores, which may be similar to a Farrow core 530 of FIG. 5. Each Farrow core 890 provides a single output sample from the 15 input samples, so the plurality of Farrow cores 890 provides 15 output samples 895.

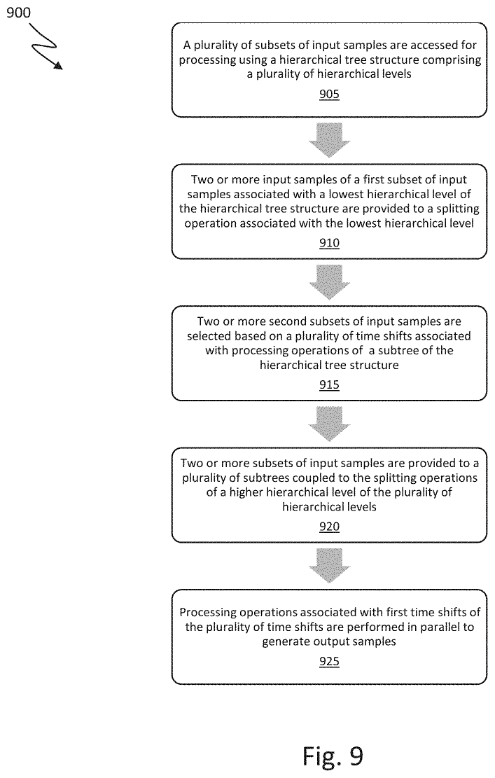

FIG. 9 is a flowchart depicting an exemplary sequence of computer implemented steps 900 for generating a plurality of output samples based on a set of input samples according to embodiments of the present invention.

At step 905, a plurality of subsets of input samples are accessed for processing using a hierarchical tree structure comprising a plurality of hierarchical levels.

At step 910, two or more input samples of a first subset of input samples associated with a lowest hierarchical level of the hierarchical tree structure are provided to a splitting operation associated with the lowest hierarchical level. The splitting operation is operable to provide the two or more subsets to a plurality of processing cores coupled to the respective splitting operation of the lowest hierarchical level.

At step 915, two or more second subsets of input samples are selected based on a plurality of time shifts associated with processing operations of a subtree of the hierarchical tree structure.

At step 920, two or more subsets of input samples are provided to a plurality of subtrees coupled to the splitting operations of a higher hierarchical level of the plurality of hierarchical levels.

At step 925, processing operations associated with first time shifts of the plurality of time shifts are performed in parallel to generate output samples.

According to some embodiments, each splitting node is configured to provide two or more subsets of the input samples of the given splitting node. Each splitting node of a given hierarchical level is receiving input samples from a splitting node of the next higher hierarchical level, and feeds splitting nodes of the next lower hierarchical level with its output subsets of the input samples. The input samples, for example P+M−1 samples, of the sample distribution logic is the input of the splitting node on the highest hierarchical level, while the output subsets, for example subsets of M samples, of the sample distribution logic is the output subsets of the splitting nodes on the lowest hierarchical level.

According to embodiments, an input sample rate of the input samples of the digital signal processing apparatus is lower than or equal to a target output sample rate of the output samples of the digital signal processing apparatus. The digital signal processing apparatus is configured to provide a generally denser output sampling than the input sampling.

Flexible (or almost arbitrary) sample rate conversion can be supported, where the target sample rate is greater than or equal to the source sample rate, and embodiments can include digital delay with sub-sample resolution, which is a special case of a flexible (or almost arbitrary) sample rate conversion, when the target rate is equal to the source rate, pulse-shaping for digital pattern generation, introduction of timing jitter, e.g., for controlled signal conditioning in measurement instruments, and/or timing error compensation of interleaved digital-to-analogue converters (DAC).

According to some embodiments, the digital signal processing apparatus includes a time accumulator configured to keep track of the time shifts and to trigger obtaining new input samples in an input register. The input register is coupled to the sample distribution logic, for example via a selection block. Obtaining new input samples is triggered, whenever the time shift overflows a predetermined multiple, such as P, of a sampling period of the input samples. The time accumulator accumulates fractional samples in the half-open interval [0: P) in P×Δt increments. Whenever the accumulator overflows, it requests, for example, P input samples.

According to embodiments, the number of samples in a set of input samples of a plurality of splitting nodes in a same hierarchical level of the sample distribution logic are identical. The number of samples in each of the subsets of input samples provided by a plurality of splitting nodes as output samples in a same hierarchical level of the sample distribution logic can also be identical. For example, the number of samples in a set of input samples and a number of samples in a set of output samples of a first splitting node is equal to the number of samples in a set of input samples and the number of samples in a set of output samples of a second splitting node on the same hierarchical level.

According to some embodiments, the splitting nodes of the same hierarchical levels have equal amount of input samples and equal amount of output subsets of the input samples, with equal amount of samples in the subsets, has a modular structure, having hierarchical levels built up from the same modules, which makes the production and/or planning of the sample distribution logic simpler, cheaper and/or faster.

According to some embodiments, the number of samples in a set of input samples of a given splitting node is larger than a number of samples in each of the subsets of samples provided to splitting nodes of a next lower hierarchical level or to processing cores as input samples. A given splitting node divides the input samples into two or more sets or subsets of input samples with equal amount of samples and provides them as output samples. The two or more subsets of the input samples may intersect with each other.

According to some embodiments, the number of input samples of a given splitting node is larger than the number of samples in any output subset of the given splitting node. The output subsets of the given splitting node contain equal number of samples, which are provided as a set of input samples of splitting nodes of the next lower hierarchical level or as a set of input samples of processing cores.

According to some embodiments, the sample distribution logic is configured such that a number of samples per subset provided to splitting nodes as input samples by respective splitting node of a next hierarchical level step-wisely decreases with decreasing hierarchical levels. The sample distribution logic is a chain of splitting nodes, wherein each splitting node receives one output subset as input samples from a splitting node of a higher hierarchical level and feeds with output subsets two or more splitting nodes on a lower hierarchical level. The splitting nodes on the lowest hierarchical level provide two or more output subsets to respective two or more processing cores. From top to the bottom the number of input samples of the splitting nodes of different hierarchical levels decrease along with the number of samples in the output subsets of splitting nodes of lower and lower hierarchical levels.

According to embodiments, a number of input samples of a respective splitting node and/or a number of samples in each of the subsets of input samples provided by a respective splitting node as output samples are based on the number of samples in the subset of the set of input samples provided to a single processing core denoted as M, and/or on the hierarchical level of a respective splitting node denoted as h, and/or on a factorization of the number of processing cores denoted as P, into integer factors, denoted as pₖ.

According to some embodiments, there is a relationship between the number of input samples and a number of output samples of a given splitting node, which is dependent on the hierarchical level of the splitting node, the number of input samples of a processing core, and an integer factor of the number of processing cores. Defining this relation as a mathematical equation results in a clear and straightforward understanding of the splitting node and/or the whole sample distribution logic.

According to some embodiments, the number of subsets of input samples provided by a respective splitting node depends on a factorization of the number of processing cores denoted as P, into integer factors, denoted as pₖ. pₖ represents integer factors, not necessarily prime factors of P, such that P is described by P=Πₖ₌₀^{H-1}pₖ. In the equation P represents the number of processing cores, k represents a running variable between 0 and (H−1) and H represents the total number of factors in the chosen integer factorization. A given splitting node divides a set of input samples into subsets of samples, and the subsets may overlap. The number of subsets of the set of input samples provided by the given splitting node is depending on an integer factor, pₖ, of the number of processing cores, P. As the number of subsets provided by a given splitting node is dependent on an integer factor of the number of processing cores results in an integer number of hierarchical levels. Splitting nodes of the same hierarchical levels have the same amount of samples in a set of input samples and providing identical number of subsets with the identical number of samples in the subset.

According to embodiments, the number of subsets of input samples provided by a respective splitting node of a given hierarchical level is denoted as pₕ and it represents one of the integer factors, pₖ, of the number of processing cores, P. pₕ is one element of a set of the integer factors, not necessarily prime factors, pₖ of the number of processing core, P, such that P is described by P=Πₖ₌₀^{H-1}pₖ, as discussed above. h in pₕ represents the hierarchical level of the respective splitting node. The lowest hierarchical level is described by h=0 and h increases with increasing hierarchical levels.

According to some embodiments, the number of input samples of a respective splitting node is based on the following equation:

$${N}_{input} = ( {{\prod }^{h}}_{k = 0} {p}_{k} ) + M - 1$$

In the equation Nᵢₙₚᵤₜ represents the number of input samples, pₖ represents integer factors, not necessarily prime factors, of the number of processing cores, P, such that P=Πₖ₌₀^{H-1}pₖ, as discussed above, h represents the hierarchical level of respective splitting node, where a lowest hierarchical level is described by h=0 and h increases with the increasing hierarchical level, and M represents the number of samples in the subset of the set of input samples provided to a single processing core.

According to some embodiments, the number of samples in each of the subsets of input samples provided by a respective splitting node as output samples are based on a following equation:

$${N}_{output} = \frac{1}{{p}_{h}} ( {{\prod }^{h}}_{k = 0} {p}_{k} ) + M - 1$$

In the equation Nₒᵤₜₚᵤₜ represents the number of samples in each of the subsets of input samples provided by a respective splitting node as output samples, pₕ represents the number of subsets of input samples provided by a respective splitting node of a given hierarchy level, pₖ represents integer factors, but not necessarily prime factors, of the number of processing cores, P, such that P=Πₖ₌₀^{H-1}pₖ, as discussed above, h represents the hierarchical level of respective splitting node, where a lowest hierarchical level is described by h=0 and h increases with the increasing hierarchical level, and M represents the number of samples in the subsets of the set of input samples provided to a single processing core.

According to some embodiments, a splitting node is configured to assign samples in a set of input samples to a plurality of subtrees or processing cores, and the respective splitting node in a respective hierarchical level of the sample distribution logic is configured to select samples and/or output samples from the input samples such that same or different, contiguous subsets of the input samples, starting at the same or different sample indices, are provided to each of the subtrees or processing cores. Further, the starting index of a subset of input samples provided to each subtree is dependent on the hierarchical level, h, of respective splitting node and/or on the integer factors chosen for the factorization, pₖ, of the number of processing cores, P, and/or on the time shift, Δt, and/or on the time information assigned to the set of input samples fracₚᵣₑᵥ.

A given splitting node can provide two or more subsets of a set of input samples provided to the given splitting node. The subsets of the input sample provided by the splitting node may overlap with each other, meaning the same sample may be included by two or more subsets of a set of input samples. The different subsets of the input samples start at different sample indices and are provided to each of the subtrees or processing cores.

Starting on different sample indices is resulting in non-identical subsets of the input sample, wherein a sample may be contained by more than one subtree of the set of input samples. The starting index of a subset of a set of input samples is provided to each subtree and/or is calculated by the given splitting node. Having a defined starting index and/or a formula to calculate the starting index of a subset of the set of input samples will provide replicable subsets of the set of input samples.

According to some embodiments, the starting index of the subset of input samples provided to the subtree with index i of a respective splitting node is based on the equation:

indexᵢ=(pₕ−1)W+└fracₚᵣₑᵥ−i×W×Δt┘

In the equation the index, represents a starting index of a subset of input samples pₕ represents the number of subsets of input samples provided by respective splitting node, W is described by

$$W = \frac{1}{{p}_{h}} ( {\prod }_{k = 0}^{h} {p}_{k} ) , ,$$

where pₖ represents an integer factor, not necessarily a prime factor of P, such P=Πₖ₌₀^{H-1}pₖ, as discussed above, h represents the hierarchical level of respective splitting node, where a lowest hierarchical level is described by h=0 and h increases with increasing hierarchical level, └.┘ represents the largest integer less than or equal to the argument, fracₚᵣₑᵥ represents the time information assigned to the set of input samples, and Δt represents the time shift, for example, between samples provided by neighboring processing cores.

According to some embodiments, a splitting node on the respective hierarchical level is configured to assign time information to each subtree based on a time information, fracₚᵣₑᵥ, assigned to the input samples of the respective splitting node, and/or on the hierarchical level, h, of the respective splitting node and/or on the integer factors chosen to the factorization, pₖ, of the number of processing cores, P, and/or on the time shift, Δt. The time information assigned to the input samples of a respective splitting node is used for calculating the starting index of a subset of a set of input samples. The time information is dependent on the hierarchical level of the given splitting node, and/or on an integer factor of the number of processing cores and/or on a time shift.

According to some embodiments, time information assigned to the subtree with index i of the respective splitting node, for example denoted as [symbol] “frac” [symbol] _i, is based on the equation:

fracᵢ=(fracₚᵣₑᵥ−i×W×Δt)−└fracₚᵣₑᵥ−i×W×Δt┘,

In the equation fracᵢ represents a time information assigned to the subtree with index i, where i=0 refers to the first subtree, W is described by the equation

$$W = \frac{1}{{p}_{h}} ( {\prod }_{k = 0}^{h} {p}_{k} ) ,$$

discussed above, └.┘ represents the largest integer less than or equal to the argument, fracₚᵣₑᵥ represents the time information assigned to the set of input samples, and Δt represents the time shift, for example between samples provided by neighboring processing cores.

According to some embodiments, the digital signal processing apparatus includes an input register configured to store a plurality of input samples. Storing the samples in an input register allows selecting a set of the stored samples to be distributed by a distribution logic to the processing cores. One sample can be selected and/or distributed to one or more processing core several times.

According to some embodiments, the input register is a shift register. Because a limited number of input samples need to be stored, a shift register is sufficient to store the limited number of input samples. A shift register is a viable solution for storing a limited number of samples, it is widely used, simple to use and cost effective.

According to some embodiments, the digital signal processing apparatus including a selector configured to select the set of input samples of the sample distribution logic from the plurality of input samples. A selector selects a set of samples to be distributed by the sample distribution logic to the processing cores from a plurality of input samples stored in the input register, resulting in a preselection of the input samples.

According to some embodiments, the length of the time shifts used in splitting nodes of the same hierarchical level and/or used in splitting nodes of different hierarchical levels, is equidistant or non-equidistant, if a timing jitter is applied. As time shifts are associated with processing operations, a variability of the length of the time shifts, which might be equidistant or non-equidistant, results in performing variable processing operations with equidistant or non-equidistant time shifts. Non-equidistant time shifts could be used to compensate for timing errors present in interleaved high speed DAC implementations.

According to some embodiments, the signal processing apparatus performs an interpolation between the input samples. The digital signal processing apparatus obtains a new input sample whenever the time shift overflows a predetermined multiple of a sampling period of the input samples in the time accumulator and outputs an output sample via the plurality of processing cores performing processing operations associated with different time shifts. The time shifts associated with the processing operations is a fraction of a sampling period of the input samples, resulting that the output samples are interpolated samples located between the input samples.

According to some embodiments, the digital signal processing apparatus performs a convolution. As a given processing core performs the processing operation, obtaining a plurality of input samples and outputting a single output sample, the processing core performs a weighted mean operation or a convolution operation, which provides a single output element from a multiple input element.

According to some embodiments, the plurality of processing cores implement a Farrow structure. A Farrow structure is a widely used implementation of an interpolator, which makes it an easy-to-apply, off-the-shelf, cost effective solutions.

According to some embodiments, the construction of different subtrees are derived from same or different choices of integer factors, pₖ, of the number of processing cores, P. For example, when P=16 the number of processing cores can be factored as 16=(2×2×2)×2 for one part of the tree and/or as 16=(4×2)×2 for a different part of the tree.

According to some embodiments, the construction of different subtrees are derived from same or different orderings of integer factors, pₖ, of the number of processing cores, P. For example, when P=16 the number of processing cores could be factored as 16=2×4×2 for one part of the tree and/or as 16=4×2×2 for a different part of the tree.

Embodiments of the present invention are thus described. While the present invention has been described in particular embodiments, it should be appreciated that the present invention should not be construed as limited by such embodiments, but rather construed according to the following claims.

What is claimed is:

1. A signal processing apparatus for providing a plurality of output samples based on a plurality of input samples, the signal processing apparatus comprising:
a sample distribution logic unit operable to provide input samples of the plurality of input samples to a plurality of processing cores, wherein the plurality of processing cores are operable to perform processing operations on the input samples associated with different time shifts;
a hierarchical tree structure comprising a plurality of hierarchical levels and comprising a lowest hierarchical level, wherein the plurality of hierarchical levels comprise input samples of the plurality of input samples;
a first splitting node associated with the lowest hierarchical level operable to provide two or more subsets to a plurality of processing cores coupled to the first splitting node; and
a second splitting node associated with a hierarchical level that is higher than the lowest hierarchical level, wherein the second splitting node is operable to provide two or more subsets of input samples of the plurality of input samples associated with the second splitting node to a plurality of subtrees coupled to the second splitting node, and
wherein the first and second splitting nodes are operable to select a subset of input samples of the plurality of input samples in accordance with a range of time shifts associated with the plurality of processing cores to generate the plurality of output samples.

2. The signal processing apparatus of claim 1, wherein the plurality of processing cores are further operable to perform processing operations associated with the range of time shifts in parallel to generate the plurality of output samples.

3. The signal processing apparatus of claim 1, wherein an input sample rate of the plurality of input samples is no greater than a target output sample rate of the output samples.

4. The signal processing apparatus of claim 1, further comprising:
an input register coupled to the sample distribution logic; and
a time accumulator operable to track time shift and to cause new input samples to be obtained by the input register when the time shift overflows a predetermined multiple of a sampling period of the input samples.

5. The signal processing apparatus of claim 1, wherein a number of input samples of a given splitting node is larger than a number of input samples provided to splitting nodes of a next lower hierarchical level and larger than a number of input samples provided to the plurality of processing cores as input samples.

6. The signal processing apparatus of claim 1, wherein the sample distribution logic unit is operable to provide input samples to the first and second splitting nodes according to the hierarchical tree in a step-wise manner that decreases with each hierarchical level transversed of the hierarchical tree.

7. The signal processing apparatus of claim 1, wherein a number of input samples provided to the first and second splitting nodes is based on at least one of: a number of input samples or subset of input samples provided to a single processing core of the plurality of processing cores; a hierarchical level of the first or second splitting node; and a factorization of a number of processing cores as integer factors.

8. The signal processing apparatus of claim 1, wherein a number of input samples provided between the first and second splitting node is based on a factorization of a number of processing cores as integer factors.

9. The signal processing apparatus of claim 1, wherein the first splitting node is associated with a first hierarchical level of the hierarchical tree structure, wherein a number of subsets of input samples provided by the first splitting node is based on at least one of: a number of processing cores; a total number of factors of a selected integer factorization; and the first hierarchical level.

10. The signal processing apparatus of claim 9, wherein the number of subsets of input samples provided by the first splitting node is further based on a number of samples of a subset of samples provided to a single processing core.

11. The signal processing apparatus of claim 1, wherein the first and second splitting nodes are configured to:
assign input samples to a plurality of subtrees or processing cores; and
provide assigned input samples to the respective subtrees of the hierarchical tree structure or to respective processing cores,
wherein a starting index of the assigned input samples is based on at least one of: a hierarchy level associated with a splitting node; an integer factor for factorization of the number of processing cores; and a time shift and time information assigned to the assigned input samples.

12. The signal processing apparatus of claim 1, further comprising an input register configured to store input samples.

13. The signal processing apparatus of claim 12, wherein the input register comprises a shift register.

14. The signal processing apparatus of claim 1, further comprising a selector configured to select the subset of input samples from the plurality of input samples to provide to the sample distribution logic unit.

15. The signal processing apparatus of claim 1, wherein a length of the time shifts is equidistant.

16. The signal processing apparatus of claim 1, wherein the plurality of processing cores performs an interpolation between the plurality of input samples.

17. The signal processing apparatus of claim 1, wherein the sample distribution logic unit is operable to perform a convolution on the input samples.

18. The signal processing apparatus of claim 1, wherein the plurality of processing cores are operable to process the input samples using a Farrow structure.

19. A method of generating a plurality of output samples based on a set of input samples, the method comprising:
accessing a plurality of subsets of input samples for processing using a hierarchical tree structure comprising a plurality of hierarchical levels;
providing two or more input samples of a first subset of input samples associated with a lowest hierarchical level of the hierarchical tree structure to a splitting operation associated with the lowest hierarchical level, wherein the splitting operation is operable to provide the two or more subsets to a plurality of processing cores coupled to the respective splitting operation of the lowest hierarchical level;
selecting two or more second subsets of input samples based on a plurality of time shifts associated with processing operations of a subtree of the hierarchical tree structure;
providing two or more subsets of input samples to a plurality of subtrees coupled to the splitting operations of a higher hierarchical level of the plurality of hierarchical levels; and
performing processing operations associated with first time shifts of the plurality of time shifts in parallel to generate the plurality of output samples.

20. A non-transitory computer-readable storage medium having embedded therein program instructions, which when executed by one or more processors of a device, causes the device to execute a method of generating a plurality of output samples based on a set of input samples, the method comprising:
accessing a plurality of subsets of input samples for processing using a hierarchical tree structure comprising a plurality of hierarchical levels;
providing two or more input samples of a first subset of input samples associated with a lowest hierarchical level of the hierarchical tree structure to a splitting operation associated with the lowest hierarchical level, wherein the splitting operation is operable to provide the two or more subsets to a plurality of processing cores coupled to the respective splitting operation of the lowest hierarchical level;
selecting two or more second subsets of input samples based on a plurality of time shifts associated with processing operations of a subtree of the hierarchical tree structure;
providing two or more subsets of input samples to a plurality of subtrees coupled to the splitting operations of a higher hierarchical level of the plurality of hierarchical levels; and
performing processing operations associated with first time shifts of the plurality of time shifts in parallel to generate the plurality of output samples.
